(19) United States
(12) Patent Application Publication
(10) Pub. No.: US 2025/0334759 A1
(43) Pub. Date: Oct. 30, 2025

(54) OPTICAL MODULE AND METHOD OF MANUFACTURING OPTICAL MODULE

(71) Applicant: FURUKAWA ELECTRIC CO., LTD., Tokyo (JP)

(72) Inventors: Taketsugu SAWAMURA, Tokyo (JP); Kazuhiko KASHIMA, Tokyo (JP); Kyoko NAGAI, Tokyo (JP); Kohei UMETA, Tokyo (JP); Nitidet THUDSALINGKARNSAKUL, Phranakorn Sri Ayutthaya (TH); Rattanaporn SUKSOMBOON, Phranakorn Sri Ayutthaya (TH); Punramon RATTAKORN, Phranakorn Sri Ayutthaya (TH)

(73) Assignee: FURUKAWA ELECTRIC CO., LTD., Tokyo (JP)

(21) Appl. No.: 19/264,991

(22) Filed: Jul. 10, 2025

Related U.S. Application Data
(63) Continuation of application No. PCT/JP2024/004388, filed on Feb. 8, 2024.

(30) Foreign Application Priority Data
Feb. 8, 2023 (JP) 2023-017281

(51) Int. Cl. G02B 6/42

(52) U.S. Cl. CPC G02B 6/4228

(57) ABSTRACT

An optical module includes: a base having a first surface facing a first direction, and a second surface that faces the first direction and that is away from the first surface in a second direction orthogonal to the first direction; an optical element provided on the first surface; an optical fiber fixing portion including a groove configured to at least partially accommodate a core wire obtained by removing a coating from an optical fiber; and an alignment mark provided either at a first position away from the groove in a direction opposite to the second direction or at a second position shifted from the first position in a direction opposite to a third direction orthogonal to both of the first direction and the second direction, as viewed in the direction opposite to the first direction.

### CROSS-REFERENCE TO RELATED APPLICATIONS

This application is a continuation of International Application No. PCT/JP2024/004388, filed on Feb. 8, 2024 which claims the benefit of priority of the prior Japanese Patent Application No. 2023-017281, filed on Feb. 8, 2023, the entire contents of which are incorporated herein by reference.

### BACKGROUND OF THE INVENTION

### 1. Field of the Invention

The present disclosure relates to an optical module and a method of manufacturing the optical module.

### 2. Description of the Related Art

In the related art, an optical module including a light emitting element and an optical fiber to which output light of the light emitting element is coupled is known (for example, WO 2017/010570 A). In the optical module of WO 2017/010570 A, a light emitting element and an optical fiber are fixed on a base.

### SUMMARY OF THE INVENTION

In this type of optical module, when positioning accuracy between an optical element such as a light emitting element and an optical fiber is low, coupling efficiency of light between the optical element and the optical fiber is reduced. That is, it is beneficial to obtain an optical module capable of more easily or more reliably securing positioning accuracy between the optical element and the optical fiber.

Therefore, it is desirable to obtain, for example, an improved novel optical module and a method of manufacturing the optical module that can more easily or more reliably ensure the positioning accuracy between the optical element and the optical fiber.

In some embodiments, an optical module includes: a base having a first surface facing a first direction, and a second surface that faces the first direction and that is away from the first surface in a second direction orthogonal to the first direction; an optical element either from which light is output in the second direction or to which light is input in a direction opposite to the second direction, the optical element being provided on the first surface; an optical fiber fixing portion including a groove that is recessed from the second surface in a direction opposite to the first direction and that extends in the second direction in the base, the groove being configured to at least partially accommodate a core wire obtained by removing a coating from an optical fiber either to which the light output from the optical element is input or from which the light to be input to the optical element is output; and an alignment mark provided either at a first position away from the groove in a direction opposite to the second direction or at a second position shifted from the first position in a direction opposite to a third direction orthogonal to both of the first direction and the second direction, as viewed in the direction opposite to the first direction.

In some embodiments, an optical module includes: a base having a first surface facing a first direction, and a second surface that faces the first direction and that is away from the first surface in a second direction orthogonal to the first direction; an optical element either from which light is output in the second direction or to which light is input in a direction opposite to the second direction, the optical element being provided on the first surface; and an optical fiber fixing portion including a groove that is recessed from the second surface in a direction opposite to the first direction and that extends in the second direction in the base, the groove being configured to at least partially accommodate a core wire obtained by removing a coating from an optical fiber either to which the light output from the optical element is input or from which the light to be input to the optical element is output. In the groove, the core wire is in no contact with the optical fiber fixing portion and an adhesive is interposed between the core wire and the optical fiber fixing portion.

In some embodiments, provided is a method of manufacturing an optical module. The method includes: forming a first surface facing a first direction in a base; forming, in the base, a second surface that faces the first direction and that is away from the first surface in a second direction orthogonal to the first direction; forming an alignment mark fixed to the base; forming, in the second surface, a groove that is recessed in a direction opposite to the first direction, extends in the second direction, and is aligned with the alignment mark formed in the second direction; providing an optical element on the first surface so as to have a predetermined positional relationship between the optical element and the alignment mark; and fixing a core wire obtained by removing a coating from an optical fiber to the base with an adhesive while at least partially accommodate the core wire in the groove.

The above and other objects, features, advantages and technical and industrial significance of this disclosure will be better understood by reading the following detailed description of presently preferred embodiments of the disclosure, when considered in connection with the accompanying drawings.

### BRIEF DESCRIPTION OF THE DRAWINGS

FIG. 1 is an exemplary schematic perspective view of an optical module according to a first embodiment;

FIG. 2 is an exemplary and schematic plan view of the optical module of the first embodiment;

FIG. 3 is a cross-sectional view taken along line III-III of FIG. 2;

FIG. 4 is an exemplary schematic plan view of a base of the optical module according to the first embodiment;

FIG. 5 is a flowchart illustrating an example of a procedure of the method of manufacturing the optical module according to the first embodiment;

FIG. 6 is an exemplary schematic plan view of a base of an optical module according to a second embodiment;

FIG. 7 is an exemplary schematic plan view of a part of a base of an optical module according to a third embodiment;

FIG. 8 is an exemplary schematic plan view of a base of an optical module according to a fourth embodiment;

FIG. 9 is an exemplary schematic plan view of a base of an optical module according to a fifth embodiment;

FIG. 10 is a cross-sectional view of an optical module of a sixth embodiment at the same position as FIG. 3;

FIG. 11 is a cross-sectional view of an optical module of a seventh embodiment at the same position as FIG. 3;

FIG. 12 is a cross-sectional view of an optical module of an eighth embodiment at the same position as FIG. 3;

FIG. 13 is an exemplary schematic perspective view of an optical module according to a ninth embodiment; and

FIG. 14 is an exemplary and schematic plan view of the optical module of a tenth embodiment.

### DETAILED DESCRIPTION

Hereinafter, exemplary embodiments are disclosed. The configurations of the embodiments described below, and the functions and results (effects) provided by the configurations are examples. The embodiments can include configurations other than those disclosed in the following embodiments. In addition, according to the disclosure, it is possible to obtain at least one of various effects (including derivative effects) obtained by the configuration.

A plurality of embodiments described below have similar configurations. Therefore, according to the configuration of each embodiment, similar functions and effects based on the similar configuration can be obtained. In addition, in the following description, similar reference numerals are given to similar configurations, and redundant description may be omitted.

In the present specification, ordinal numbers are given for convenience in order to distinguish directions, members, parts, portions, and the like, and do not indicate priority or order, and do not limit the number.

In each figure, the X direction is represented by an arrow X, the Y direction is represented by an arrow Y, and the Z direction is represented by an arrow Z. The X direction, the Y direction, and the Z direction intersect each other and are orthogonal to each other. In addition, the X direction may be referred to as a longitudinal direction or an extending direction, the Y direction may be referred to as a lateral direction or a width direction, and the Z direction may be referred to as a thickness direction or a height direction.

### First Embodiment

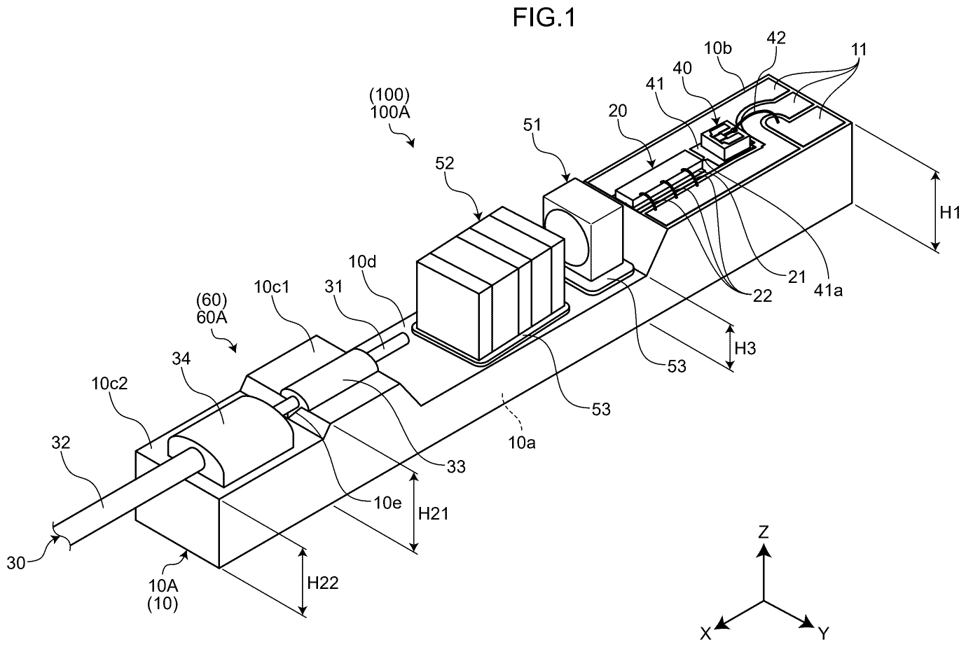

FIG. 1 is a perspective view of an optical module 100A (100) according to a first embodiment. As illustrated in FIG. 1, the optical module 100 includes a base 10A (10), a light emitting element 20, an optical fiber 30, a light receiving element 40, a lens 51, and an isolator 52. The light emitting element 20 is an example of the optical element.

The base 10 has a substantially square rod shape. The base 10 has a substantially constant width in the Y direction and extends in the X direction. The base 10 is made of, for example, silicon. Note that the base 10 may be made of, for example, a ceramic having a relatively high thermal conductivity, such as aluminum nitride, or may be made of a material other than the above materials.

The base 10 has a surface 10a. The surface 10a faces the direction opposite to the Z direction, intersects with and is orthogonal to the Z direction, and extends in the X direction with a substantially constant width in the Y direction. In addition, the surface 10a has a quadrangular shape. The surface 10a may also be referred to as a bottom surface or a lower surface.

In addition, the base 10A (10) has surfaces 10b, 10d, 10c1, and 10c2 on the side opposite to the surface 10a. Each of the surfaces 10b, 10d, 10c1, and 10c2 faces the Z direction, intersects with and is orthogonal to the Z direction, and extends in the X direction with a substantially constant width in the Y direction. Each of the surfaces 10b, 10d, 10c1, and 10c2 has, for example, a quadrangular shape. The surfaces 10b, 10d, 10c1, and 10c2 are arranged in this order in the X direction, and the surface 10c1 is away from the surface 10b in the X direction. The surfaces 10b, 10d, 10c1, and 10c2 may also be referred to as top surfaces or upper surfaces. The Z direction is an example of a first direction, and the X direction is an example of a second direction. In addition, the surface 10b is an example of a first surface, and the surface 10c1 is an example of a second surface. Note that the surfaces 10b, 10d, 10c1, and 10c2 have a quadrangular shape as an example in the present embodiment, but are not limited thereto, and may have a shape different from the quadrangular shape.

Heights H1, H3, H21, and H22 (thicknesses) of the surfaces 10b, 10d, 10c1, and 10c2 from the surface 10a in the Z direction, respectively, are different from each other. In the present embodiment, as an example, the heights H1, H3, H21, and H22 have a relationship of H1≥H21>H22>H3. That is, the surfaces 10b, 10d, 10c1, and 10c2 form steps. In addition, the surfaces 10b, 10d, 10c1, and 10c2 are used as surfaces for fixing components. That is, the surfaces 10b, 10d, 10c1, and 10c2 may also be referred to as component fixing surfaces or component mounting surfaces.

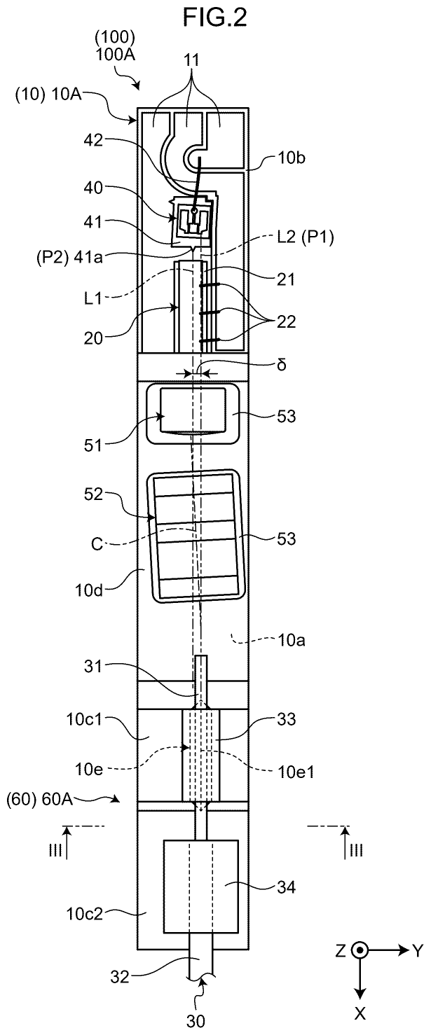

FIG. 2 is a plan view of the optical module 100A (100). As illustrated in FIGS. 1 and 2, a plurality of electrodes 11 are formed on the surface 10b. The light emitting element 20 and the light receiving element 40 are surface-mounted on the same electrode 11 via bonding materials 21 and 41, respectively. The bonding materials 21 and 41 are applied onto the electrode 11, for example, and are solder foil or solder paste, for example. In addition, the terminal electrodes provided at the end portions of the light emitting element 20 and the light receiving element 40 in the Z direction are electrically connected to different electrodes 11 via bonding wires 22 and 42. The electrode 11 may also be referred to as an electric conductor pattern.

The light emitting element 20 outputs the laser beam in the X direction. The light output from the light emitting element 20 in the X direction is input to a core wire 31 of the optical fiber 30 via the lens 51 and the isolator 52. That is, the lens 51 and the isolator 52 are located between the light emitting element 20 and the optical fiber 30. The light emitting element 20 is, for example, a laser light emitting element.

As illustrated in FIG. 2, that is, when viewed in the direction opposite to the Z direction, in the present embodiment, the center line C of the isolator 52 is arranged slightly inclined with respect to the X direction in order to prevent return light from end-face reflection, so that output light from the isolator 52 translates in the Y direction with respect to input light to the isolator 52. That is, the light output from the light emitting element 20 is offset by the offset amount δ in the Y direction by passing through the isolator 52. The lens 51 and the isolator 52 are fixed onto the surface 10d via an adhesive 53. The lens 51 and the isolator 52 are examples of the first optical component.

Further, the light emitting element 20 also outputs the laser light in the direction opposite to the X direction. The light output from the light emitting element 20 in the direction opposite to the X direction is input to the light receiving element 40 provided on the side opposite to the optical fiber 30 with respect to the light emitting element 20. The light receiving element 40 detects, for example, the intensity of the light output from the light emitting element 20. The light receiving element 40 is, for example, a photodiode.

The optical fiber 30 includes a core wire 31 and a coating 32 surrounding the core wire 31. The optical fiber 30 is fixed to the base 10 via adhesives 33 and 34.

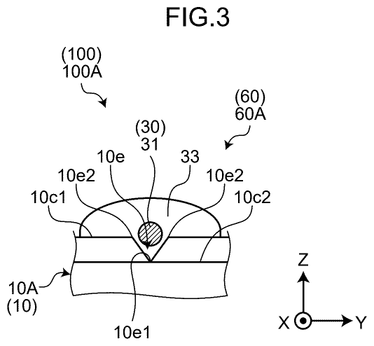

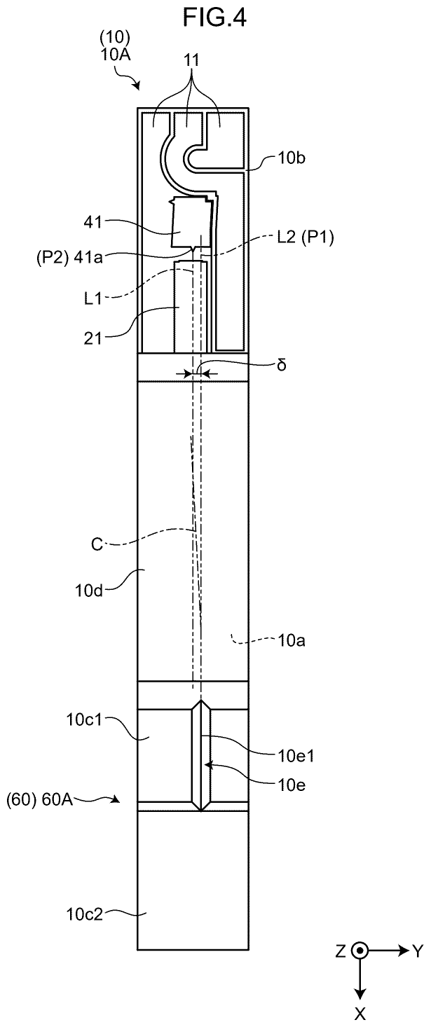

FIG. 3 is a cross-sectional view taken along line III-III of FIG. 2. In addition, FIG. 4 is a plan view of the base 10A (10). As illustrated in FIG. 3, a groove 10e is recessed from the surface 10c1 of the base 10 in the direction opposite to the Z direction. Further, as illustrated in FIG. 4, the groove 10e has a substantially V-shaped cross-sectional shape as illustrated in FIG. 3 and extends in the X direction.

As illustrated in FIG. 3, the core wire 31 exposed by partially removing the coating 32 at the end of the optical fiber 30 is at least partially accommodated in the groove 10e. As illustrated in FIGS. 1 to 3, the adhesive 33 surrounds the periphery of the core wire 31, is interposed between the core wire 31 and the surface 10c1 or the inner surface of the groove 10e, and adheres the core wire 31 to the base 10. In the base 10, a part of the surface 10c1 and the inner surface of the groove 10e constitute an optical fiber fixing portion 60A (60). In the present embodiment, the core wire 31 is not in direct contact with the inner surface of the groove 10e. If the core wire 31 comes into contact with the inner surface of the groove 10e, the position of the core wire 31 is limited by the position of the groove 10e, and there is a possibility that the core wire 31 cannot be positioned with higher accuracy. In this regard, in the present embodiment, since the core wire 31 is not in direct contact with the inner surface of the groove 10e, it is possible to suppress a decrease in positioning accuracy due to restriction of the position of the core wire 31 by the position of the groove 10e.

In addition, as illustrated in FIGS. 1 and 2, a portion of the optical fiber 30 in the vicinity of a portion from which the coating 32 has been removed is placed on the surface 10c2 in a state of being covered with the coating 32. The adhesive 34 surrounds the coating 32 and is interposed between the coating 32 and the surface 10c2 to bond the coating 32 to the base 10. In the base 10, a part of the surface 10c2 constitutes the optical fiber fixing portion 60A (60). Note that a part of the core wire 31 may be covered with the adhesive 34.

In such a configuration, in order to enhance the coupling efficiency of the light output from the light emitting element 20 to the core wire 31 of the optical fiber 30, it is necessary that the light emitting element 20 and the core wire 31 of the optical fiber 30 are accurately positioned. Therefore, as illustrated in FIGS. 2 and 4, in the present embodiment, as an example, an alignment mark 41a for positioning is provided in the bonding material 41 of the light receiving element 40. The alignment mark 41a is formed at an edge located at an end of the bonding material 41 in the X direction and is a protrusion protruding in the X direction from the edge. According to such a configuration, at the time of manufacturing the optical module 100, since the groove 10e can be formed with reference to the alignment mark 41a and the light emitting element 20 can be mounted, the positioning accuracy between the light emitting element 20 and the core wire 31 of the optical fiber 30 can be enhanced, and furthermore, the coupling efficiency of the light output from the light emitting element 20 to the core wire 31 of the optical fiber 30 can be enhanced. Further, according to the configuration of the present embodiment, it is possible to obtain an advantage that the alignment mark 41a can be relatively easily formed when the bonding material 41 is formed.

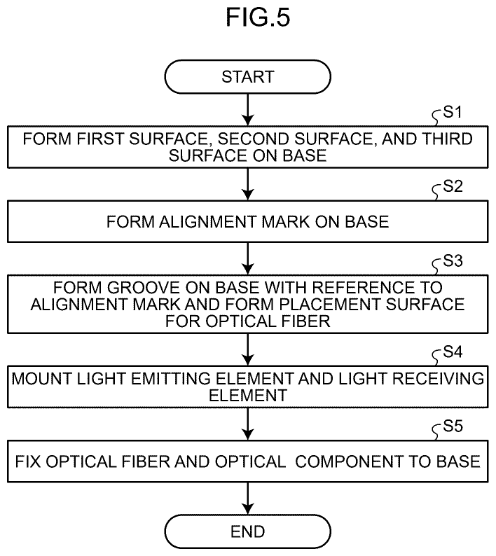

FIG. 5 is a flowchart illustrating an example of a manufacturing procedure of the optical module 100. As illustrated in FIG. 5, first, a surface 10b (first surface), a surface 10c1 (second surface), and a surface 10d (third surface) are formed in the base 10 by a known semiconductor process or the like (Step S1). When the surface 10b and the surface 10c1 are flush with each other, in Step S1, first, a surface to be the surface 10b and the surface 10c1 are formed, and then, the surface 10d is formed in an intermediate portion of the surface in the X direction by etching or the like using an appropriate mask pattern, whereby the surface 10b, the surface 10c1, and the surface 10d can be formed.

Next, as illustrated in FIG. 5, the alignment mark 41a is formed on the base 10 (Step S2). When the alignment mark 41a is formed in the bonding material 41 as in the present embodiment, the electrode 11 is formed after Step S1 and before Step S2. In Step S2, the bonding material 41 is formed on the electrode 11, and the alignment mark 41a is provided in the bonding material 41.

Next, as illustrated in FIG. 5, a groove 10e is formed with reference to the alignment mark 41a (Step S3). FIG. 4 is a plan view of the base 10 after Step S3. As described above, in the present embodiment, the light output from the light emitting element 20 is offset by the offset amount δ in the Y direction by passing through the lens 51 and the isolator 52. Therefore, in Step S3, as illustrated in FIG. 4, when viewed in the direction opposite to the Z direction, the groove 10e is formed such that the valley line 10e1 of the groove 10e is along a virtual line L2 offset by the offset amount δ in the Y direction with respect to a virtual line L1 passing through the alignment mark 41a that has been already formed. In Step S3, the groove 10e can be formed by etching or the like using an appropriate mask pattern. According to Step S3, in the product of the optical module 100, as illustrated in FIG. 2, when viewed in the direction opposite to the Z direction, the reference point of the alignment mark 41a is provided at a position P2 shifted by the offset amount δ in the direction opposite to the Y direction with respect to a position P1 away from the valley line 10e1 of the groove 10e in the direction opposite to the X direction. The alignment mark 41a is located on the side opposite to the optical fiber 30 with respect to the light emitting element 20, but the disclosure is not limited thereto. Further, the reference point of the alignment mark 41a is set at a position where the position of the alignment mark 41a in the Y direction can be easily specified by a tip having a pointed shape in the X direction or in the direction opposite to the X direction. The virtual line L1 is an example of a first virtual line, and the virtual line L2 is an example of a second virtual line. The position P1 is an example of a first position, and the position P2 is an example of a second position.

Here, as illustrated in FIG. 3, the deepest position of the groove 10e in the Z direction, that is, the position of the valley line 10e1 in the present embodiment, and the position of the surface 10c2 in the Z direction are substantially the same. Therefore, in Step S3, the groove 10e and the surface 10c2 can be formed simultaneously by etching or the like using an appropriate mask pattern. If the deepest position of the groove 10e and the position of the surface 10c2 are different in the Z direction, the process of forming the groove 10e and the surface 10c2 becomes more complicated. In this regard, according to the present embodiment, since the groove 10e and the surface 10c2 can be formed simultaneously, the base 10 and thus the optical module 100 can be more easily or more quickly manufactured.

Next, as illustrated in FIG. 5, the light emitting element 20 and the light receiving element 40 are mounted (Step S4), and the optical fiber 30, the lens 51, and the isolator 52 (optical component) are fixed by the adhesives 33,34, and 53 (Step S5).

In Step S4, the light emitting element 20 and the light receiving element 40 are mounted on the base 10 while being positioned with respect to the alignment mark 41a. At this time, the light emitting element 20 and the light receiving element 40 are arranged so as to have a predetermined positional relationship with the alignment mark 41a when viewed in the direction opposite to the Z direction, specifically, for example, so as to be aligned with the alignment mark 41a in the X direction. Note that “arranged in the X direction” means that they are arranged in substantially a line along the X direction at intervals, and the order of arrangement is not limited.

In addition, in Step S5, while light is output from the light emitting element 20 in a state where the adhesives 33 and 53 are not completely solidified, and the intensity of light coupled to the optical fiber 30 is measured, the position of the distal end of the core wire 31, the position and posture of the lens 51, the position and posture of the isolator 52, and the like may be adjusted to increase the coupling efficiency of light to the optical fiber 30. In particular, according to the configuration of the present embodiment, since the offset amount of the light output from the light emitting element 20 can be adjusted by adjusting the inclination angle of the center line C of the isolator 52 with respect to the X direction (see FIG. 2), it is possible to obtain an effect of easily enhancing the coupling efficiency.

Further, in the adjustment in Step S5, after the adhesive 34 is solidified and the base portion of the optical fiber 30 covered with the coating 32 is fixed to the base 10, the position of the core wire 31 may be finely adjusted in a state where the adhesive 33 is not completely solidified. Therefore, the adhesive 34 may be an adhesive that solidifies faster than the adhesive 33, or the component of the adhesive 33 and the component of the adhesive 34 may be different from each other. In the optical fiber fixing portion 60 of the base 10, the groove 10e and the surface 10c1 as a portion where the core wire 31 is fixed by the adhesive 33 are an example of a first fixing portion, and the surface 10c2 as a portion where a portion of the optical fiber 30 covered with the coating 32 is fixed to the base 10 by the adhesive 34 is an example of a second fixing portion. The adhesive 33 is an example of a first adhesive, and the adhesive 34 is an example of a second adhesive.

As described above, according to the structure and the method of the present embodiment, by forming the groove 10e with reference to the alignment mark 41a, it is possible to obtain an effect to more accurately position the light emitting element 20 and the core wire 31 of the optical fiber 30, and furthermore, it is possible to more easily or more reliably enhance the coupling efficiency of the light output from the light emitting element 20 to the optical fiber 30.

In the present embodiment, the surface 10b and the surface 10c1 are provided on one base 10, that is, in the same portion. If the base 10 is formed of a plurality of portions and the surface 10b and the surface 10c1 are provided in different portions, the positional deviation between the surface 10b and the surface 10c1 becomes larger. Therefore, in order to more reliably accommodate the core wire 31 in the groove 10e, in other words, in order to absorb the positional deviation of the groove 10e with respect to the core wire 31 due to manufacturing variation between the surface 10b and the surface 10c1, it is necessary to further increase the width and depth of the groove 10e, that is, the cross-sectional area of the groove 10e. In this case, inconvenience may be caused, for example, the amount of the adhesive 33 is further increased as the cross-sectional area of the groove 10e is larger, or the positional displacement of the core wire 31 is more likely to be increased as the movable range of the core wire 31 in the groove 10e is larger. In this regard, according to the present embodiment, since the surface 10b and the surface 10c1 are provided in one base 10, that is, in the same portion, the positional deviation of the groove 10e with respect to the alignment mark 41a can be further reduced, and thus, the cross-sectional area of the groove 10e can be further reduced, so that the effect of suppressing the occurrence of the above-described inconvenience can be obtained. In addition, according to the present embodiment, by reducing the amount of the adhesive 33, it is also possible to obtain an effect of suppressing a decrease in reliability due to deterioration of the adhesive 33.

### Second Embodiment

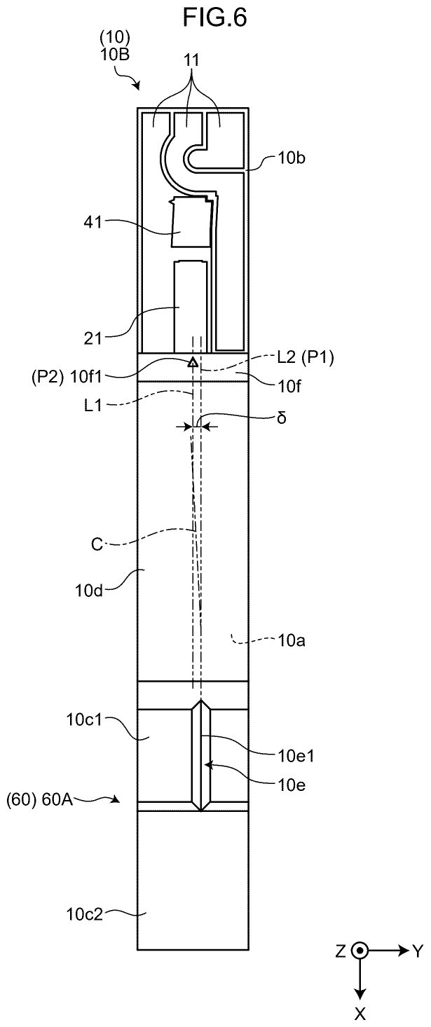

FIG. 6 is a plan view of a base 10B (10) of the second embodiment. The base 10B (10) can be incorporated in the optical module 100 instead of the base 10A of the first embodiment.

In the present embodiment, an alignment mark 10f1 is provided as a recess positioned in the inclined surface 10f between the surface 10b and the surface 10c1 of the base 10B (10). The alignment mark 10f1 may be provided before the surfaces 10b and 10c1 are formed or may be provided after the surfaces 10b and 10c1 are formed by a known semiconductor process or the like. The inclined surface 10f is formed in the step of forming the surface 10d. The inclined surface 10f may also be referred to as a boundary surface or a side surface.

In the present embodiment, the alignment mark 10f1 is provided between the light emitting element 20 and the optical fiber 30.

Also in the present embodiment, by forming the groove 10e with reference to the alignment mark 10f1, it is possible to obtain an effect to more accurately position the light emitting element 20 and the core wire 31 of the optical fiber 30, and furthermore, it is possible to more easily or more reliably enhance the coupling efficiency of the light output from the light emitting element 20 to the optical fiber 30.

### Third Embodiment

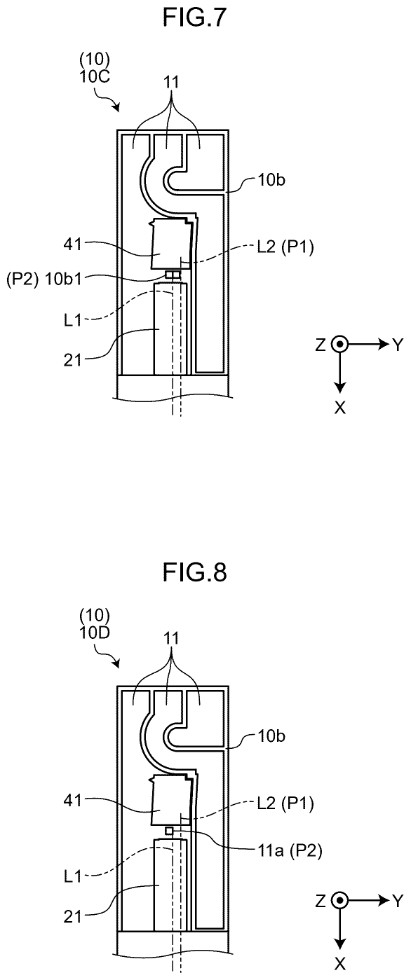

FIG. 7 is a plan view of a part of a base 10C (10) of the third embodiment. The base 10C (10) can be incorporated in the optical module 100 instead of the base 10A of the first embodiment.

In the present embodiment, an alignment mark 10b1 is provided as a recess provided in the surface 10b. The alignment mark 10b1 has a valley line extending in the X direction at the center portion of the recess in the Y direction, and the valley line can be used as a reference point of the alignment mark 10b1. Since the surface 10b is covered with the electrode 11, the alignment mark 10b1 is also covered with the electric conductor layer of the electrode 11. Note that the alignment mark 10b1 is not necessarily covered with the electric conductor layer.

Also in the present embodiment, by forming the groove 10e with reference to the alignment mark 10b1, it is possible to obtain an effect to more accurately position the light emitting element 20 and the core wire 31 of the optical fiber 30, and furthermore, it is possible to more easily or more reliably enhance the coupling efficiency of the light output from the light emitting element 20 to the optical fiber 30.

### Fourth Embodiment

FIG. 8 is a plan view of a part of a base 10D (10) of an optical module 100 according to a fourth embodiment. The base 10D (10) can be incorporated in the optical module 100 instead of the base 10A of the first embodiment.

In the present embodiment, an alignment mark 11a is constituted by an edge of an opening provided in the electrode 11. The edge as the alignment mark 11a has a portion extending in the X direction at an end of the opening in the Y direction, and the portion can be used as a reference point of the alignment mark 11a. Note that the edge in this case is not limited to the edge of the opening, that is, the inner boundary, and may be a part of the outer boundary of the electrode 11.

Also in the present embodiment, by forming the groove 10e with reference to the alignment mark 11a, it is possible to obtain an effect to more accurately position the light emitting element 20 and the core wire 31 of the optical fiber 30, and furthermore, it is possible to more easily or more reliably enhance the coupling efficiency of the light output from the light emitting element 20 to the optical fiber 30.

### Fifth Embodiment

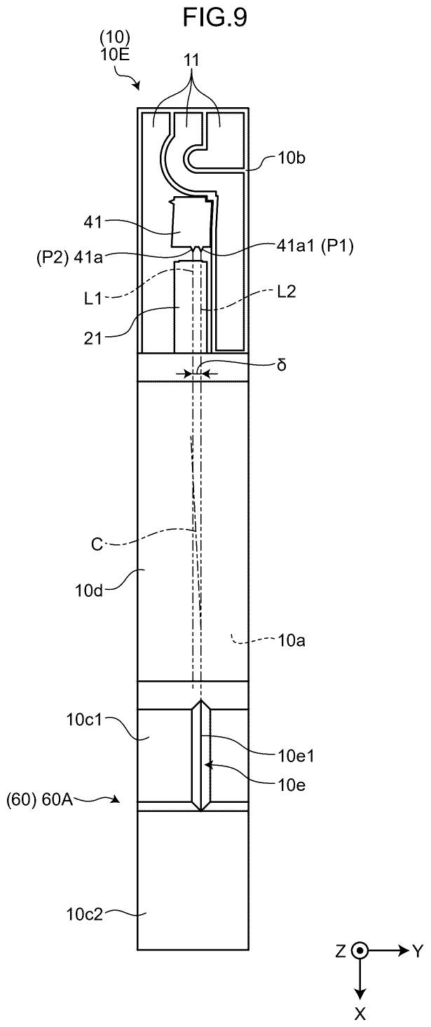

FIG. 9 is a plan view of a base 10E (10) of the optical module 100 of a fifth embodiment. The base 10E (10) can be incorporated in the optical module 100 instead of the base 10A of the first embodiment.

In the present embodiment, in addition to the same alignment mark 41a as in the first embodiment, the bonding material 41 is provided with an alignment mark 41a1 provided at a position P1 away from the valley line 10e1 of the groove 10e in the direction opposite to the X direction. In this case, the alignment mark 41a can be used for positioning the light emitting element 20, and the alignment mark 41a1 can be used for positioning the groove 10e (valley line 10e1).

According to the present embodiment, by forming the groove 10e with reference to the alignment mark 41a1, it is possible to more accurately position the light emitting element 20 and the core wire 31 of the optical fiber 30, and furthermore, it is possible to more easily or more reliably enhance the coupling efficiency of the light output from the light emitting element 20 to the optical fiber 30.

### Sixth Embodiment

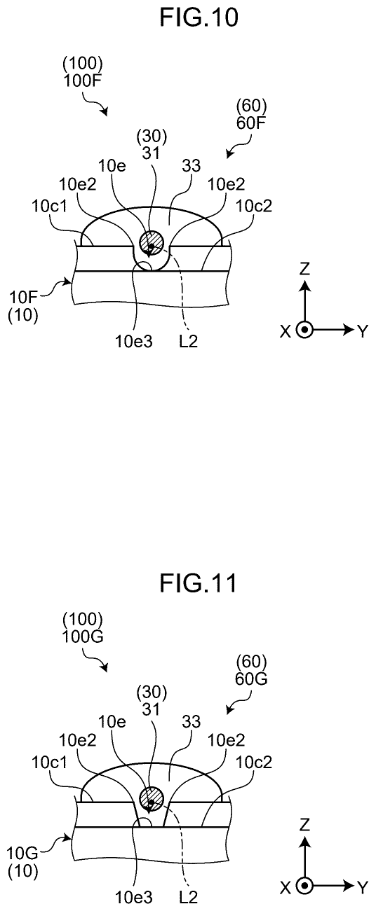

FIG. 10 is a cross-sectional view of an optical module 100F (100) of the sixth embodiment at the same position as FIG. 3, that is, at an optical fiber fixing portion 60F (60). As illustrated in FIG. 10, in the present embodiment, a cross section of the groove 10e of a base 10F (10) intersecting the X direction has a substantially U shape. The groove 10e extends in the X direction with the cross section having the substantially U shape.

As is clear from FIG. 10, the valley line 10e1 as in the first embodiment is not formed in a bottom surface 10e3 of the groove 10e. In such a case, referring to a center line of two opening edges 10e2 extending in the X direction in the groove 10e of the surface 10c1 as a virtual line L2, a process similar to that of the first embodiment is performed. That is, in Step S3 of FIG. 5, when viewed in the direction opposite to the Z direction, the groove 10e is formed such that the center line of the two opening edges 10e2 is along a virtual line L2 offset by the offset amount δ in the Y direction with respect to a virtual line L1 passing through the alignment mark 41a that has been already formed. Also in this case, according to Step S3, in the product of the optical module 100, when viewed in the direction opposite to the Z direction, the reference point of the alignment mark 41a is provided at a position P2 shifted from the position P1 by the offset amount δ in the direction opposite to the Y direction, the position P1 being away from the center line (line segment) of the two opening edges 10e2 in the opposite to the X direction.

Also in the present embodiment, by forming the groove 10e with reference to the alignment mark 41a1, it is possible to obtain an effect to more accurately position the light emitting element 20 and the core wire 31 of the optical fiber 30, and furthermore, it is possible to more easily or more reliably enhance the coupling efficiency of the light output from the light emitting element 20 to the optical fiber 30. In the first embodiment, similarly to the present embodiment, the above-described process may be performed using the center line of the two opening edges 10e2 extending in the X direction in the groove 10e of the surface 10c1 as the virtual line L2.

### Seventh Embodiment

FIG. 11 is a cross-sectional view of an optical module 100G (100) of the seventh embodiment at the same position as FIG. 3, that is, at an optical fiber fixing portion 60G (60). As illustrated in FIG. 11, in the present embodiment, a cross section of the groove 10e of a base 10G (10) intersecting the X direction has a substantially inverted trapezoidal shape. The groove 10e extends in the X direction with the cross section having the substantially inverted trapezoidal shape.

Also in the present embodiment, similarly to the sixth embodiment described above, a process similar to that of the first embodiment may be performed with a center line of two opening edges 10e2 extending in the X direction in the groove 10e as a virtual line L2. That is, the same effects as those of the sixth embodiment can be obtained also in the present embodiment.

### Eighth Embodiment

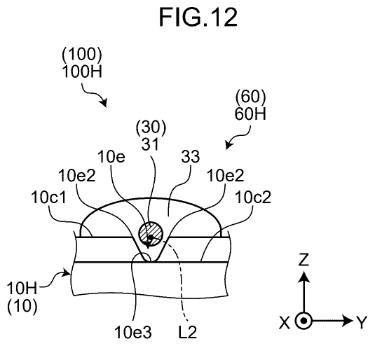

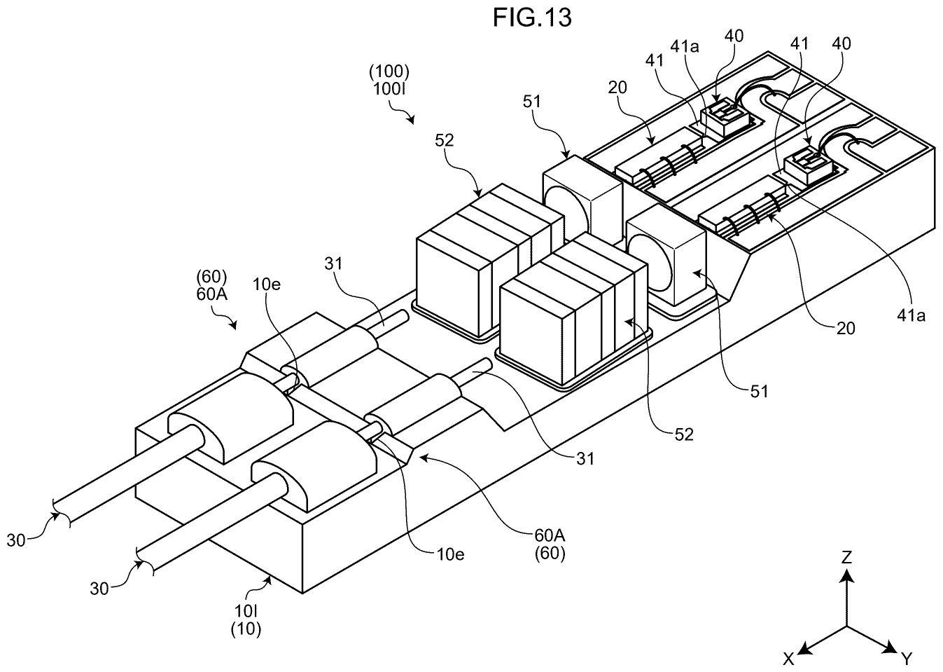

FIG. 12 is a cross-sectional view of an optical module 100H (100) of the eighth embodiment at the same position as FIG. 3, that is, at an optical fiber fixing portion 60H (60). As illustrated in FIG. 11, in the present embodiment, a cross section of the groove 10e of a base 10H (10) intersecting the X direction has a substantially V shape with rounded bottom. The groove 10e extends in the X direction with the cross section having the substantially V shape with rounded bottom.

Also in the present embodiment, similarly to the sixth embodiment described above, a process similar to that of the first embodiment may be performed with a center line of two opening edges 10e2 extending in the X direction in the groove 10e as a virtual line L2. That is, the same effects as those of the sixth embodiment can be obtained also in the present embodiment.

### Ninth Embodiment

FIG. 13 is a perspective view of an optical module 100I (100) according to a ninth embodiment. In the present embodiment, a base 10I (10) has a substantially plate shape having a wider width in the Y direction, and a plurality of combinations of the light emitting element 20, the lens 51, the isolator 52, and the optical fiber 30 are shared. Also in the present embodiment, since the alignment mark 41a is provided for each combination, the same effects as those of the first embodiment can be obtained. The number of combinations is not limited to two, and may be three or more.

### Tenth Embodiment

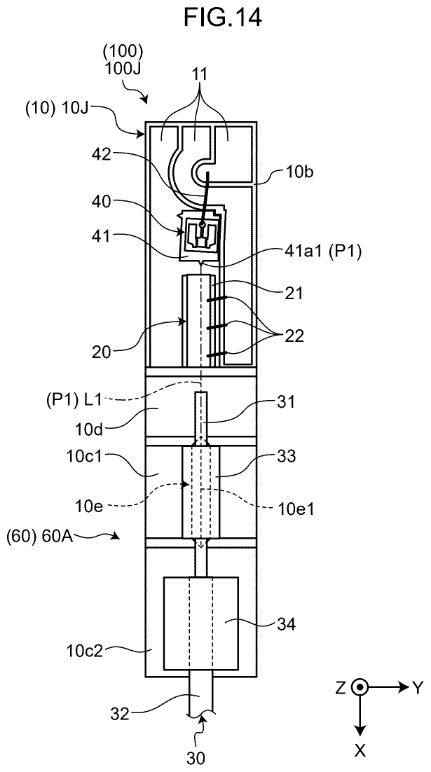

FIG. 14 is a plan view of an optical module 100J (100). In the present embodiment, a base 10J (10) is not provided with the lens 51 and the isolator 52 as in the first embodiment. Therefore, the light output from the light emitting element 20 is not offset in the Y direction as in the first embodiment. In this case, the optical fiber 30 may be a lensed fiber.

In the present embodiment, as in the fifth embodiment (see FIG. 9), there is provided an alignment mark 41a1 provided at a position P1 away from the valley line 10e1 of the groove 10e in the direction opposite to the X direction. The alignment mark 41a1 can be used for positioning the groove 10e (valley line 10e1). Also in the present embodiment, the same effects as those of other embodiments can be obtained.

Although the embodiments have been exemplified above, the above embodiments are merely examples, and are not intended to limit the scope of the invention. The above-described embodiments can be implemented in various other forms, and various omissions, substitutions, combinations, and changes can be made without departing from the gist of the invention. In addition, specifications (structure, type, direction, model, size, length, width, thickness, height, number, arrangement, position, material, and the like) of each configuration, shape, and the like can be appropriately changed and implemented.

For example, the alignment mark may be fixed to the base, and may be provided on and/or in the base or various objects fixed to the base. For example, the alignment mark may be provided in a bonding material for an element different from the optical element. In addition, the alignment mark may have a portion that can be recognized by a camera or an operator, and can be implemented with the specifications such as various shapes, positions, sizes. Further, the alignment mark may be provided during the step of forming the groove. In this case, the alignment mark and the groove can be aligned more accurately. Furthermore, the optical element is not limited to the light emitting element, and may be, for example, an element different from the light emitting element that outputs light, such as an optical modulator, or may be an element to which light is input, such as a light receiving element or a coherent mixer. In addition, the optical fiber is not limited to an optical fiber to which light from the optical element is input, and may be an optical fiber from which light is output toward the optical element.

According to the disclosure, a novel and improved optical module and a method of manufacturing an optical module can be obtained.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical module comprising:
a base having
a first surface facing a first direction, and
a second surface that faces the first direction and that is away from the first surface in a second direction orthogonal to the first direction;
an optical element either from which light is output in the second direction or to which light is input in a direction opposite to the second direction, the optical element being provided on the first surface;
an optical fiber fixing portion including a groove that is recessed from the second surface in a direction opposite to the first direction and that extends in the second direction in the base, the groove being configured to at least partially accommodate a core wire obtained by removing a coating from an optical fiber either to which the light output from the optical element is input or from which the light to be input to the optical element is output; and
an alignment mark provided either at a first position away from the groove in a direction opposite to the second direction or at a second position shifted from the first position in a direction opposite to a third direction orthogonal to both of the first direction and the second direction, as viewed in the direction opposite to the first direction.

2. The optical module according to claim 1, further comprising:
a first optical component that is located between the optical element and the optical fiber, the first optical component being configured to either offset the light output from the optical element in the third direction to input the offset light to the optical fiber or offset the light output from the optical fiber in the direction opposite to the third direction to input the offset light to the optical element,
wherein the groove of the optical fiber fixing portion is configured to at least partially accommodate the core wire from which the coating of the optical fiber to which the light output from the optical element is input has been removed, and
the alignment mark is provided at the second position shifted from the first position in the direction opposite to the third direction by an offset amount caused by the first optical component as viewed in the direction opposite to the first direction.

3. The optical module according to claim 1, wherein the first surface and the second surface are provided on a same portion.

4. The optical module according to claim 1, wherein the first position is a position away from a valley line of the groove in the direction opposite to the second direction, the valley line extending in the second direction.

5. The optical module according to claim 4, wherein a cross section of the groove intersecting the second direction has a substantially V-shape.

6. The optical module according to claim 1, wherein the first position is a position away from a center line of the groove of the second surface in the direction opposite to the second direction, the center line being a center line of two opening edges extending in the second direction in the groove.

7. The optical module according to claim 6, wherein a cross section of the groove intersecting the second direction has a substantially U-shape.

8. The optical module according to claim 6, wherein a cross section of the groove intersecting the second direction has a substantially inverted trapezoidal shape.

9. The optical module according to claim 6, wherein a cross section of the groove intersecting the second direction has a substantially V-shape with a rounded bottom.

10. The optical module according to claim 1, wherein the alignment mark is located on a side opposite to the optical fiber with respect to the optical element.

11. The optical module according to claim 1, wherein the alignment mark is located between the optical element and the optical fiber.

12. The optical module according to claim 1, further comprising a second optical component provided on the first surface on a side opposite to the optical fiber with respect to the optical element,
wherein the alignment mark is provided in a bonding material that fixes the second optical component.

13. The optical module according to claim 12, wherein the second optical component is a light receiving element configured to receive the light output from the optical element.

14. The optical module according to claim 1, wherein the alignment mark is configured by an edge of an electric conductor pattern provided on the first surface.

15. The optical module according to claim 1, wherein the alignment mark is configured as a recess that is provided in the base and that is recessed in the direction opposite to the first direction.

16. The optical module according to claim 2, wherein the first optical component is a component capable of changing an input position of the light from the first optical component to the optical fiber by adjusting a position and a posture of the first optical component.

17. The optical module according to claim 16, wherein the first optical component includes at least one of a lens or an isolator.

18. The optical module according to claim 1, wherein
the optical fiber fixing portion includes:
a first fixing portion provided with the groove, the first fixing portion being configured to fix the core wire from which the coating is removed, with a first adhesive; and
a second fixing portion positioned on a side opposite to the optical element with respect to the groove, the second fixing portion being configured to fix a portion that is included in the optical fiber and that is covered with the coating, with a second adhesive.

19. The optical module according to claim 18, wherein a deepest position of the groove of the first fixing portion and a position of the second fixing portion are substantially a same in the first direction.

20. The optical module according to claim 18, wherein a component of the first adhesive is different from a component of the second adhesive.

21. An optical module comprising:
a base having
a first surface facing a first direction, and
a second surface that faces the first direction and that is away from the first surface in a second direction orthogonal to the first direction;
an optical element either from which light is output in the second direction or to which light is input in a direction opposite to the second direction, the optical element being provided on the first surface; and
an optical fiber fixing portion including a groove that is recessed from the second surface in a direction opposite to the first direction and that extends in the second direction in the base, the groove being configured to at least partially accommodate a core wire obtained by removing a coating from an optical fiber either to which the light output from the optical element is input or from which the light to be input to the optical element is output,
wherein in the groove, the core wire is in no contact with the optical fiber fixing portion and an adhesive is interposed between the core wire and the optical fiber fixing portion.

22. A method of manufacturing an optical module, the method comprising:
forming a first surface facing a first direction in a base;
forming, in the base, a second surface that faces the first direction and that is away from the first surface in a second direction orthogonal to the first direction;
forming an alignment mark fixed to the base;
forming, in the second surface, a groove that is recessed in a direction opposite to the first direction, extends in the second direction, and is aligned with the alignment mark formed in the second direction;
providing an optical element on the first surface so as to have a predetermined positional relationship between the optical element and the alignment mark; and
fixing a core wire obtained by removing a coating from an optical fiber to the base with an adhesive while at least partially accommodate the core wire in the groove.

23. The method of manufacturing an optical module according to claim 22, further comprising:
fixing, to the base, a first optical component that is located between the optical element and the optical fiber, the first optical component being configured to either offset light output from the optical element in a third direction orthogonal to both of the first direction and the second direction to input the offset light to the optical fiber or offset light output from the optical fiber in a direction opposite to the third direction to input the offset light to the optical element,
wherein the forming of the groove includes forming, in the second surface, the groove along a second virtual line that is offset from a first virtual line passing through the alignment mark and extending in the second direction by a predetermined offset amount in the third direction,
the predetermined offset amount is an offset amount of light caused by the first optical component.
